(19) United States
(12) Patent Application Publication
(10) Pub. No.: US 2026/0051865 A1
(43) Pub. Date: Feb. 19, 2026

(54) HIGH PRECISION JFET AMPLIFIER

(71) Applicant: Weed Instrument Company, Inc.

(72) Inventor: Horia Bendea, Cedar Park, TX (US)

(73) Assignee: Weed Instrument Company, Inc., (US)

(21) Appl. No.: 19/003,751

(22) Filed: Dec. 27, 2024

Related U.S. Application Data
(60) Provisional application No. 63/684,779, filed on Aug. 19, 2024.

(51) Int. Cl. H03F 3/45; H03F 1/30

(52) U.S. Cl. CPC H03F 3/45376; H03F 1/306

(57) ABSTRACT

An all-JFET operational amplifier provides improved accuracy and lower thermal drift than conventional JFET amplifiers. In some examples, the JFET operation amplifier includes an input stage including input transistors supplied with equal drain currents by matched current sources. In some examples, the input circuit is stabilized by local current feedback.

### BACKGROUND OF THE INVENTION

The present invention relates in general to transistors, and more specifically, to transistor amplifiers. Still more particularly, the present invention relates to junction field effect transistor (JFET) amplifiers.

The JFET is not commonly used in electronic circuits because of several disadvantages in comparison with bipolar junction transistors (BJTs) and metal-oxide-semiconductor field-effect transistors (MOSFETs). JFETs have lower gain than BJTs. JFETs are normally ON devices, which presents a challenge for many power circuits. JFETs are also difficult to manufacture with tight specifications, and their threshold voltages have a large dispersion. Driving a JFET is difficult because the gate voltage often needs to be outside the drain and source voltage range.

### SUMMARY OF THE INVENTION

The present disclosure recognizes, however, that JFETs have significant advantages that make them useful in particular niche applications. For example, JFETs have greater radiation resilience than other types of transistors and are therefore candidates for use in high radiation environments. The present disclosure presents an architecture for an all-JFET operational amplifier that provides improved accuracy and lower thermal drift when compared with conventional JFET amplifiers.

In at least some embodiments, the JFET operation amplifier includes an input stage including input transistors supplied with equal drain currents by matched current sources. In some examples, the input circuit is stabilized by local current feedback.

In at least some embodiments, a JFET amplifier seeks to maintain drain currents and drain-to-source voltages of its input transistors equal across at least a range of operating temperatures. By doing so, amplifier offset and offset temperature drift are reduced.

In at least some embodiments, a JFET amplifier includes a differential input stage including first and second JFETs supplied with equal drain currents by matched first and second current sources, respectively. The first JFET and the first current source are coupled at a control node, which controls a gain stage of the JFET amplifier.

In at least some embodiments, a JFET amplifier includes a differential input stage including matched first and second JFETs supplied with equal drain currents by matched first and second JFET current sources, respectively. A drain of the first JFET and the first current source are coupled at a control node. The JFET amplifier further includes a gain stage including a third JFET controlled by the control node and a fourth JFET coupled between a drain and a source of the second JFETs to provide local feedback current. The third and fourth JFETs are matched, such that drain-to-source voltages of the first and second JFETs are equalized.

In at least some embodiments, a method of operating a JFET amplifier includes providing first and second JFETs of a differential input stage equal drain currents by matched first and second current sources, where the first JFET and the first current source are coupled at a control node. The method further includes receiving, at the first and second JFETs, a differential input signal and amplifying, by a gain stage, a voltage at the control node.

### BRIEF DESCRIPTION OF THE DRAWINGS

FIG. 1 is a high-level block diagram of a prior art JFET amplifier;

FIG. 2 is a high-level block diagram of a JFET amplifier in accordance with one or more embodiments;

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

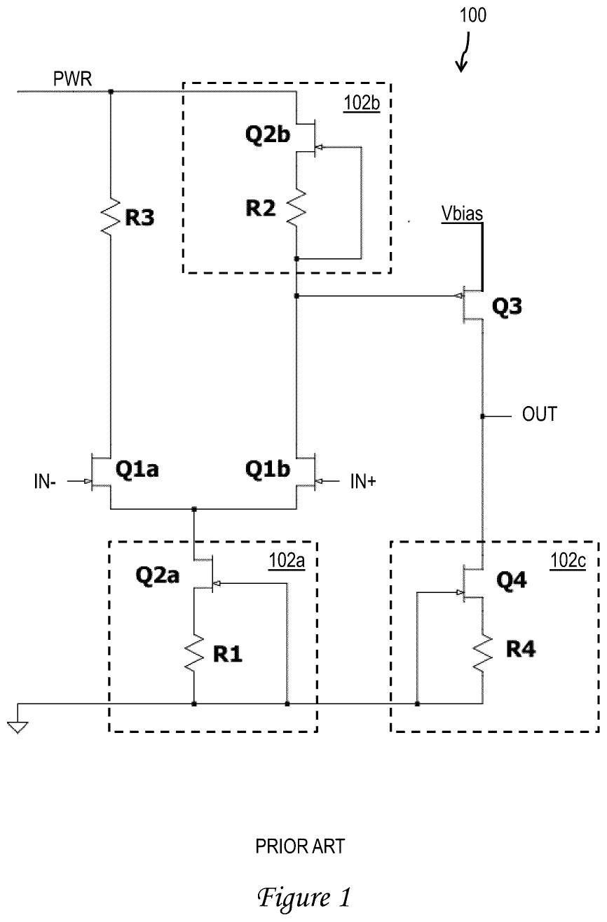

Referring now to FIG. 1, there is illustrated a high-level block diagram of a prior art JFET amplifier 100. In JFET amplifier 100, transistor Q2a and resistor R1 forms one current source 102a, and transistor Q2b and resistor R2 form another current source 102b. The impedance of resistor R1 is chosen such that current source 102a will have double the current of current source 102b. Current through transistor Q1a is the difference between current through Q2a and current through Q2b. The drain-source currents of transistors Q1a and Q1b are equal. Transistors Q1a and Q1b are a matched pair, and because they are operated at the same drain current, the amplifier's input offset is very low.

Transistors Q2a and Q2b are also implemented with a matched pair of JFETs. Because transistor Q2a is operated at twice the drain current of transistor Q2b, the two current sources 102a, 102b will have different thermal performances. As a result, the currents through input transistors Q1a and Q1b change differently with temperature. The drain current imbalance over temperature is perceived as amplifier input offset temperature drift.

Resistor R3 reduces the drain-to-source voltage of transistor Q1a to a voltage equal with transistor Q1b. Because the currents through transistors Q1a and Q1b increase with temperature, the voltage drop across resistor R3 will change significantly with temperature. Transistors Q1a and Q1b will have different drain-to-source voltages, and the difference will change with temperature. This voltage imbalance will translate into amplifier input offset and offset drift.

Transistors Q3 and Q4 together form a gain stage for JFET amplifier 100. Transistor Q3 is a P-JFET, with its source connected to an auxiliary power rail (Vaux) having a lower voltage than the main power rail (PWR). Transistor Q4 and resistor R4 form a current source 102c and act as an active load for transistor Q3.

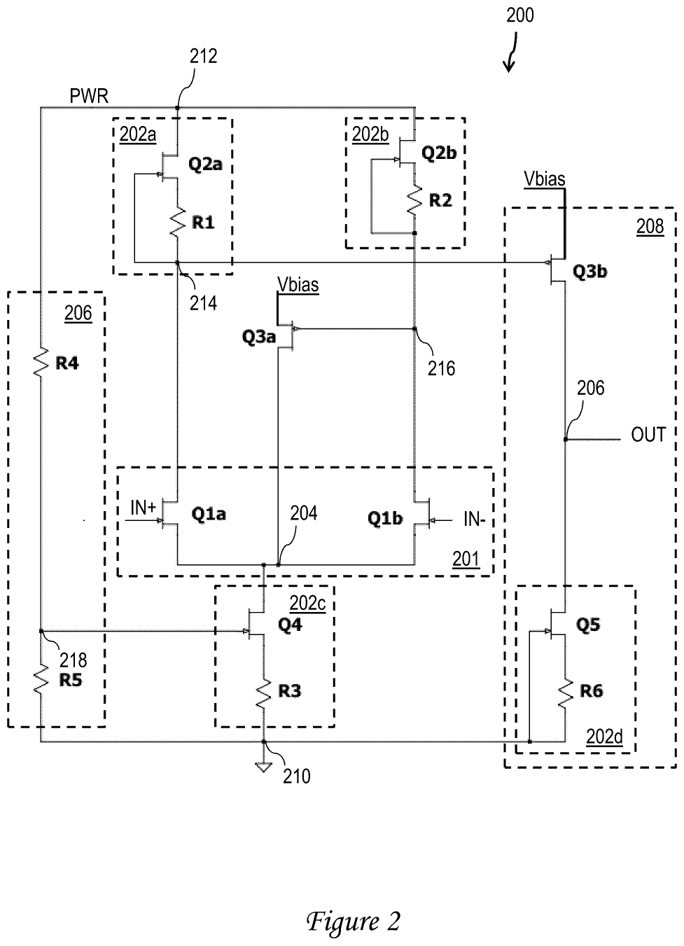

Referring now to FIG. 2, there is depicted a high-level block diagram of an all-JFET amplifier 200 in accordance with one or more embodiments. In the embodiment specifically illustrated in FIG. 2, JFET amplifier 200 includes a differential input stage 201 formed by input transistors Q1a and Q1b. Input transistors Q1a and Q1b receive a differential input signal across their gates, with the gate of input transistor Q1a being coupled to receive voltage IN+ and the gate of input transistor Q1b being coupled to receive voltage IN−. Input transistor Q1a is supplied current by high side current source 202a, which is implemented by transistor Q2a and resistor R1 and which is coupled between power node 212 and control node 214. Input transistor Q1b is similarly supplied current by high side current source 202b, which is implemented by transistor Q2b and resistor R2 and which is coupled between power node 212 and feedback node 216. Transistors Q2a and Q2b are matched transistors, and resistors R1 and R2 are of equal impedance. Consequently, current sources 202a, 202b are well matched over a wide range of operating temperatures.

Input transistors Q1a and Q1b have a common source node 204. A low side current source 202c implemented by transistor Q4 and resistor R3 is coupled between common source node 204 and ground node 210. A voltage divider 206, which is formed by resistors R4 and R5 and is coupled between power node 212 and ground node 210, is used to reduce the temperature dependency of current source 202c. The current through transistor Q4 of current source 202c is set by the voltage at divider node 218 to be higher than the sum of the currents through transistors Q2a and Q2b at all operating temperatures.

The operating point of the differential input stage 201 formed by transistors Q1a and Q1b is set by P-JFET Q3a. Transistor Q3a delivers to common source node 204 the current difference between the high side current sources 202a, 202b and low side current source 202c. Transistor Q3a creates a local feedback loop that keeps the drain voltage of transistor Q1b equal to the sum of Vbias and gate-to-source voltage of transistor Q3a.

Transistor Q3b and the current source 202d formed by transistor Q5 and resistor R6 are coupled in series to form a gain stage 208 that increases the total gain of amplifier 200. Transistors Q3a and Q3b are a matched pair, and they operate close to the cutoff gate voltage so that the gate voltages of Q3a and Q3b are almost equal. As a result, the drain voltages for input transistors Q1a and Q1b are almost equal.

Input transistors Q1a and Q1b will operate at equal drain currents due to the matched current sources 202a, 202b and at close drain-to-source voltages due to the matching of transistors Q3a and Q3b. The drain currents of input transistors Q1a and Q1b will increase with temperature, and the drain-source voltages of input transistors Q1a and Q1b will also change with temperature; however, the drain currents and drain-source voltages of input transistors Q1a and Q1b will remain equal over a large operating temperature range.

As a result of its improved symmetry, JFET amplifier 200 will have lower input offset with lower offset temperature drift as compared with conventional JFET amplifier topologies, such as that depicted in FIG. 1. As will be appreciated, JFET amplifier 200 may form a component of a larger electronic system coupled to the output node 206 of JFET amplifier 200.

As has been described, the present disclosure presents an architecture for an all-JFET operational amplifier that provides improved accuracy and lower thermal drift when compared with conventional JFET amplifiers.

In at least some embodiments, the JFET operation amplifier includes an input stage including input transistors supplied with equal drain currents by matched current sources. In some examples, the input circuit is stabilized by local current feedback.

In at least some embodiments, a JFET amplifier seeks to maintain drain currents and drain-to-source voltages of its input transistors equal across at least a range of operating temperatures. By doing so, amplifier offset and offset temperature drift are reduced.

In at least some embodiments, a JFET amplifier includes a differential input stage including first and second JFETs supplied with equal drain currents by matched first and second current sources, respectively. The first JFET and the first current source are coupled at a control node, which controls a gain stage of the JFET amplifier.

In at least some embodiments, a JFET amplifier includes a differential input stage including matched first and second JFETs supplied with equal drain currents by matched first and second JFET current sources, respectively. A drain of the first JFET and the first current source are coupled at a control node. The JFET amplifier further includes a gain stage including a third JFET controlled by the control node and a fourth JFET coupled between a drain and a source of the second JFETs to provide local feedback current. The third and fourth JFETs are matched, such that drain-to-source voltages of the first and second JFETs are equalized.

In at least some embodiments, a method of operating a JFET amplifier includes providing first and second JFETs of a differential input stage equal drain currents by matched first and second current sources, where the first JFET and the first current source are coupled at a control node. The method further includes receiving, at the first and second JFETs, a differential input signal and amplifying, by a gain stage, a voltage at the control node.

While the present invention has been particularly shown as described with reference to one or more preferred embodiments, it will be understood by those skilled in the art that various changes in form and detail may be made therein without departing from the spirit and scope of the invention.

The following definitions are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, system or apparatus that comprises a list of elements is not necessarily limited to only those elements but can include other elements not expressly listed or inherent to such composition, mixture, process, method, article, system or apparatus.

Additionally, the term “exemplary” is used herein to mean “serving as one example, instance or illustration. ” Any embodiment or design described herein as “exemplary” is not necessarily to be construed as preferred or advantageous over other embodiments or designs. The terms “at least one” and “one or more” shall be understood to include any integer number greater than or equal to one, and the term “plurality” shall be understood to include any integer number greater than or equal to two. The term “coupled” shall include both indirect connection and a direct connection, unless specified otherwise in a particular case. The terms “about,” “substantially,” “approximately,” and variations thereof, are intended to include the degree of error associated with measurement of the particular quantity based upon the equipment available at the time of filing the application. For example, “about” can include a range of ±10% or ±5%, or ±2% of a given value.

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. For the sake of brevity, conventional techniques related to making and using aspects of the invention(s) may or may not be described in detail herein, and many conventional implementation details are only mentioned briefly or are omitted entirely. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. A junction field effect transistor (JFET) amplifier, comprising:
a differential input stage including first and second JFETs supplied with equal drain currents by matched first and second current sources, respectively, wherein the first JFET and the first current source are coupled at a control node; and
a gain stage controlled by the control node.

2. The junction field effect transistor (JFET) amplifier of claim 1, wherein the gain stage includes a third JFET having a gate coupled to the control node.

3. The junction field effect transistor (JFET) amplifier of claim 2, wherein the gain stage includes a third current source coupled in series with the third JFET.

4. The junction field effect transistor (JFET) amplifier of claim 1, further comprising:
a third JFET coupled to the differential input stage to provide local current feedback, such that the differential input stage is stabilized.

5. The junction field effect transistor (JFET) amplifier of claim 4, wherein:
the third JFET has a gate, source, and drain; and
the gate of the third JFET is coupled to a drain of the second JFET and the drain of the third JFET is coupled to a source of the second JFET.

6. The junction field effect transistor (JFET) amplifier of claim 1, wherein:
the first and second JFETs have a common source node; and
the JFET amplifier includes a third current source coupled to the common source node.

7. The junction field effect transistor (JFET) amplifier of claim 6, wherein:
the third current source includes a third JFET having a gate; and
the JFET amplifier includes a voltage divider having a divider node coupled to the gate of the third JFET, wherein a voltage of the divider node sets a current through the third JFET to be greater than the sum of the currents through the first and second JFETs.

8. The junction field effect transistor (JFET) amplifier of claim 1, further comprising:
a third JFET coupled to a drain of one of the first and second JFETs to provide local feedback current;
wherein the gain stage includes a fourth JFET coupled to a drain of the other one of the first and second JFETs, such that drain-to-source voltages of the first and second JFETs are equalized.

9. The junction field effect transistor (JFET) amplifier of claim 1, wherein all transistors in the JFET amplifier are JFETs.

10. A junction field effect transistor (JFET) amplifier, comprising:
a differential input stage including matched first and second JFETs supplied with equal drain currents by matched first and second JFET current sources, respectively, wherein a drain of the first JFET and the first current source are coupled at a control node;
a gain stage including a third JFET controlled by the control node; and
a fourth JFET coupled between a drain and a source of the second JFET to provide local feedback current, wherein the third and fourth JFETs are matched, such that drain-to-source voltages of the first and second JFETs are equalized.

11. The junction field effect transistor (JFET) amplifier of claim 10, wherein the gain stage includes a third current source coupled in series with the third JFET.

12. The junction field effect transistor (JFET) amplifier of claim 10, wherein:
the first and second JFETs have a common source node; and
the JFET amplifier includes a third current source coupled to the common source node.

13. The junction field effect transistor (JFET) amplifier of claim 12, wherein:
the third current source includes a fifth JFET having a gate; and
the JFET amplifier includes a voltage divider having a divider node coupled to the gate of the fifth JFET, wherein a voltage of the divider node sets a current through the fifth JFET to be greater than the sum of the currents through the first and second JFETs.

14. The junction field effect transistor (JFET) amplifier of claim 10, wherein all transistors in the JFET amplifier are JFETs.

15. A method of operating a junction field effect transistor (JFET) amplifier, comprising:
providing first and second JFETs of a differential input stage equal drain currents by matched first and second current sources, wherein the first JFET and the first current source are coupled at a control node;
receiving, at the first and second JFETs, a differential input signal; and
amplifying, by a gain stage, a voltage at the control node.

16. The method of claim 15, wherein:
the first and second JFETs have a common source node;
the method further comprises supplying current to the common source node by a third current source.

17. The method of claim 16, wherein:
the third current source includes a third JFET having a gate; and
setting a current through the third JFET to be greater than the sum of the currents through the first and second JFETs.

18. The method of claim 15, wherein:
the first and second JFETs have a common source node; and
the method further comprises stabilizing the differential input stage by providing local current feedback utilizing a third JFET coupled between the common source node and a drain of the second JFET.

19. The method of claim 15, further comprising:
equalizing drain-to-source voltages of the first and second JFETs utilizing matched third and fourth JFETs, wherein:
the third JFET is coupled between a drain and source of one of the first and second JFETs to provide local feedback current; and
the fourth JFET forms part of the gain stage and is coupled to a drain of the other one of the first and second JFETs.
